(19) United States
(12) Patent Application Publication
(10) Pub. No.: US 2026/0372016 A1
(43) Pub. Date: Nov. 19, 2026

(54) ARRANGEMENT AND METHOD FOR QUALITY MONITORING

(71) Applicant: Infineon Technologies AG, Neubiberg (DE)

(72) Inventors: Charles Rimbert-Riviere, Soest (DE); Georg Troska, Frondenberg (DE); Gregoire Salmi, Dortmund (DE)

(73) Assignee: Infineon Technologies AG, Neubiberg (DE)

(21) Appl. No.: 19/679,999

(22) Filed: May 18, 2026

(30) Foreign Application Priority Data
May 16, 2025 (DE) 102025118993.5

(51) Int. Cl. H10P 74/20; H10W 70/68

(52) U.S. Cl. CPC H10P 74/203; H10W 70/68

(57) ABSTRACT

An arrangement comprises a dielectric insulation layer and a first metallization layer arranged on a top surface of the dielectric insulation layer. The first metallization layer comprises different sections separated by recesses. The dielectric insulation layer comprises an active region and a passive region spaced from the active region in a lateral direction. A test pattern is arranged in a top surface of an additional section of the first metallization layer arranged in the passive region, and/or in a top surface of a portion of the dielectric insulation layer arranged in the passive region and uncovered by the first metallization layer. The test pattern comprises a plurality of recesses extending from the respective top surface into the additional section of the first metallization layer or into the portion of the dielectric insulation layer in a vertical direction perpendicular to the top surface.

This application claims priority under 35 U.S.C. § 119(b) to German patent application 102025118993.5, filed on May 16, 2025.

### TECHNICAL FIELD

The instant disclosure relates to an arrangement and method for quality monitoring, in particular for monitoring the quality of substrates for semiconductor modules.

### BACKGROUND

Semiconductor module arrangements often include at least one semiconductor substrate arranged in a housing. A semiconductor arrangement including a plurality of controllable semiconductor elements (e.g., two IGBTs in a half-bridge configuration) or non-controllable semiconductor elements (e.g., arrangements of diodes) is arranged on each of the at least one substrate. Each substrate usually comprises a substrate layer (e.g., a ceramic layer), a first metallization layer deposited on a first side of the substrate layer and a second metallization layer deposited on a second side of the substrate layer. The controllable semiconductor elements are mounted, for example, on the first metallization layer. The second metallization layer may optionally be attached to a base plate. A plurality of different process steps is generally performed during production of a substrate. During further assembly of a semiconductor module arrangement, e.g., when arranging further elements on the substrate, a certain accuracy of the dimensions of the substrate generally needs to be ensured.

There is a need for an arrangement and method that allow to easily and effectively monitor a quality and accuracy of substrates for semiconductor module arrangements.

### SUMMARY

An arrangement includes a dielectric insulation layer, and a first metallization layer arranged on a top surface of the dielectric insulation layer, wherein the first metallization layer is a structured layer that includes recesses between different sections of the layer, wherein the dielectric insulation layer includes an active region, and a passive region spaced from the active region in a lateral direction, at least one section of the first metallization layer is arranged in the active region, the arrangement further includes a first test pattern arranged in a top surface of an additional section of the first metallization layer arranged in the passive region, and/or in a top surface of a portion of the dielectric insulation layer arranged in the passive region and uncovered by the first metallization layer, wherein the first test pattern includes a plurality of recesses extending from the respective top surface into the additional section of the first metallization layer or into the portion of the dielectric insulation layer in a vertical direction perpendicular to the top surface, the top surface of the additional section of the first metallization layer being a surface facing away from the substrate.

The invention may be better understood with reference to the following drawings and the description. The components in the figures are not necessarily to scale, emphasis instead being placed upon illustrating the principles of the invention. Moreover, in the figures, like referenced numerals designate corresponding parts throughout the different views.

### BRIEF DESCRIPTION OF THE DRAWINGS

FIG. 1 is a cross-sectional view of a semiconductor module arrangement.

FIG. 2 is a top view of a master card that can be separated into a plurality of substrates for semiconductor module arrangements.

FIG. 3 is a top view of an arrangement according to embodiments of the disclosure.

FIG. 4, including FIGS. 4A-4C, schematically illustrates different test patterns for arrangements according to embodiments of the disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description, as well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line or electrical connection as described herein may be a single electrically conductive element, or include at least two individual electrically conductive elements connected in series and/or parallel. Electrical lines and electrical connections may include metal and/or semiconductor material, and may be permanently electrically conductive (i.e., non-switchable).

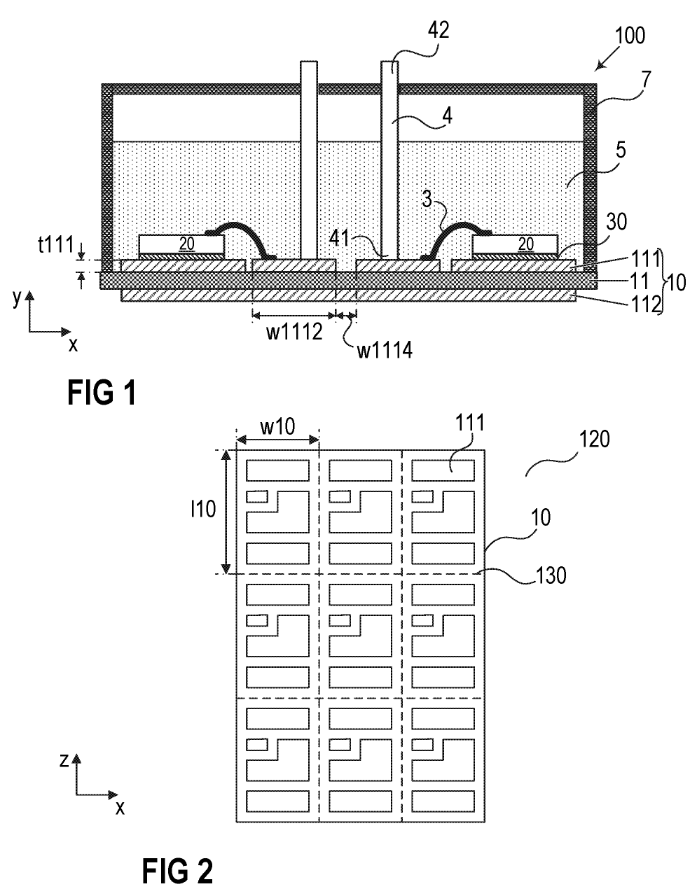

Referring to FIG. 1, a cross-sectional view of a semiconductor module arrangement 100 is illustrated. The semiconductor module arrangement 100 includes a housing 7 and a substrate 10. The substrate 10 includes a dielectric insulation layer 11, a (structured) first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. For example, the dielectric insulation layer 11 may consist of or include one of the following materials: Al₂O₃, AlN, SiC, BeO or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example. The material of the dielectric insulation layer 11 may be filled with ceramic particles, for example. Such particles may comprise, e.g., SiO₂, Al₂O₃, AlN, or BN and may have a diameter of between about 1µm and about 50µm.

The substrate 10 is arranged in a housing 7. In the example illustrated in FIG. 1, the substrate 10 forms a base surface of the housing 7, while the housing 7 itself solely comprises sidewalls and a cover. This is, however, only an example. It is also possible that the housing 7 further comprises a base surface and the substrate 10 be arranged inside the housing 7. According to another example, the substrate 10 may be mounted on a base plate (not illustrated). In some semiconductor module arrangements 100, more than one substrate 10 is arranged on a single base plate. The base plate may form a base surface of the housing 7, for example. The top of the housing 7 can either be a separate cover or lid that can be removed from the sidewalls, or may be formed integrally with at least the sidewalls of the housing 7. In the latter case, the top and at least the sidewalls of the housing 7 may be formed as a single piece such that the top cannot be removed from the sidewalls without destroying the housing.

One or more semiconductor bodies 20 may be arranged on the substrate 10. Each of the semiconductor bodies 20 arranged on the substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable controllable or non-controllable semiconductor element.

The one or more semiconductor bodies 20 may form a semiconductor arrangement on the substrate 10. In FIG. 1, only two semiconductor bodies 20 are exemplarily illustrated. The second metallization layer 112 of the substrate 10 in FIG. 1 is a continuous layer. The first metallization layer 111 is a structured layer in the example illustrated in FIG. 1. “Structured layer” means that the first metallization layer 111 is not a continuous layer, but includes recesses between different sections of the layer. Such recesses are schematically illustrated in FIG. 1. The first metallization layer 111 in this example includes four different sections. Different semiconductor bodies 20 may be mounted to the same or to different sections of the first metallization layer 111. Different sections of the first metallization layer may have no electrical connection or may be electrically connected to one or more other sections using, e.g., bonding wires 3. Electrical connections 3 may also include bonding ribbons, connection plates or conductor rails, for example, to name just a few examples. Each semiconductor body 20 of the one or more semiconductor bodies 20 may be electrically and mechanically connected to the semiconductor substrate 10 by an electrically conductive connection layer 30. Such an electrically conductive connection layer may be a solder layer, a diffusion solder layer, a layer of an electrically conductive adhesive, or a layer of a sintered metal powder, e.g., a sintered silver powder, for example.

The semiconductor module arrangement 100 illustrated in FIG. 1 further includes terminal elements 4. The terminal elements 4 are electrically connected to the first metallization layer 111 and provide an electrical connection between the inside and the outside of the housing 7. The terminal elements 4 may be electrically connected to the first metallization layer 111 with a first end 41, while a second end 42 of the terminal elements 4 protrudes out of the housing 7. The terminal elements 4 may be electrically contacted from the outside at their second end 42. The terminal elements 4 illustrated in FIG. 1, however, are only examples. Terminal elements 4 may be implemented in any other way and may be arranged at any other position. For example, one or more terminal elements 4 may be arranged close to or adjacent to the sidewalls of the housing 7. Any other suitable implementation is possible. The terminal elements 4 may consist of or include a metal such as copper, aluminum, gold, silver, or any alloys thereof, for example. Each terminal element 4 of the terminal elements 4 may be electrically and mechanically connected to the substrate 10 by means of an electrically conductive connection layer (not specifically illustrated for the terminal elements 4). Such an electrically conductive connection layer generally may be a solder layer, a diffusion solder layer, a layer of an electrically conductive adhesive, or a layer of a sintered metal powder, e.g., a sintered silver powder, for example. Alternatively, the terminal elements 4 may be directly connected to the substrate 10 using, for example, ultrasonic or laser welding. In this case, a mechanical and electrical connection is established without the use of a connection layer.

Conventional semiconductor module arrangements 100 generally further include a casting compound 5. The casting compound 5 may consist of or include a silicone gel or may be a rigid molding compound, for example. The casting compound 5 may at least partly fill the interior of the housing 7, thereby covering the components and electrical connections that are arranged on the substrate 10. The terminal elements 4 may be partly embedded in the casting compound 5. At least their second ends 42, however, are not covered by the casting compound 5 and protrude from the casting compound 5 through the housing 7, to the outside of the housing 7. The casting compound 5 is configured to protect the components and electrical connections inside the semiconductor module 100, in particular inside the housing 7, from certain environmental conditions and mechanical damage.

Different process steps are generally performed during production of a substrate 10. One or more process steps are required in order to attach the first metallization layer 111 to or form the first metallization layer 111 on the dielectric insulation layer 11, for example. The first metallization layer 111 may be formed as a continuous layer and may subsequently be structured, e.g., by means of one or more etching processes. Alternatively, it is possible that a specific mask is used during a deposition process. In this way, a structured layer can be formed, making additional etching steps superfluous. Further typical process steps during production of a substrate 10 may include, but are not limited to, e.g., laser scribing, laser marking, and provision of a solder-stop layer, formed by etching portions of the metallization prior to masking. For each of the different process steps, a minimum accuracy needs to be ensured. Certain deviations from a desired layout usually arise due to production tolerances, such deviations, however, generally should not exceed a defined deviation. For example, a deviation of a resulting thickness of the first metallization layer 111 should be within defined limits. The same applies for a deviation of a desired width of recesses between two different sections of the first metallization layer 111, for example.

Substrates 10 are usually not produced separately. In order to reduce production costs, a plurality of substrates 10 is often produced on a so-called master card 120. That is, a dielectric insulation layer 11 having the size of multiple substrates 10 may be provided, and a first metallization layer 111 having a plurality of separate sections may be formed on the master card 120. The master card 120 may subsequently be separated into a plurality of separate substrates 10. These separate substrates 10 may have identical metallization patterns, or they may have different patterns. They may all be of identical dimensions, or of varying dimensions. A master card 120 including a plurality of identical substrates 10 is schematically illustrated in FIG. 2. Each substrate 10 of the plurality of substrates 10 may have a width w10 in a first horizontal direction x and a length l10 in a second horizontal direction z perpendicular to the first horizontal directionx. The master card 120 generally comprises one or more separation lines 130, each separation line 130 defining a line along which two substrates 10 of the plurality of substrates 10 are to be separated. According to some examples, a perforation may be formed along each of the one or more separation lines 130, or a thickness of the dielectric insulation layer 11 may be reduced along each of the one or more separation lines 130. In this way, the substrates 10 may subsequently be separated from each other by means of a breaking process, for example. It is, however, also possible that the substrates 10 are separated from each other by means of any kind of cutting (e.g., laser cutting) or sawing process, for example.

Further components (e.g., semiconductor bodies 20, terminal elements 4, electrical connections 3, etc.) may be arranged on the individual substrates 10 either before or after separating the substrates 10. In order to be able to accurately arrange the components in their desired positions on the respective substrate 10, however, a minimally desired accuracy of the individual substrates 10 and the structures formed thereon (e.g., section(s) of first metallization layer 111, perforations along separation lines 130, etc.) needs to be ensured. Any deviations need to be known during further assembly of the substrates 10. A deviation generally depends on the process parameters that are used for the different process steps during production of the substrates 10 (e.g., temperatures of baths, or concentrations of chemicals such as acids). As the process parameters are generally constant during production of all substrates 10 of a certain type, a deviation from any desired dimensions is generally the same for every substrate 10 produced under the same conditions.

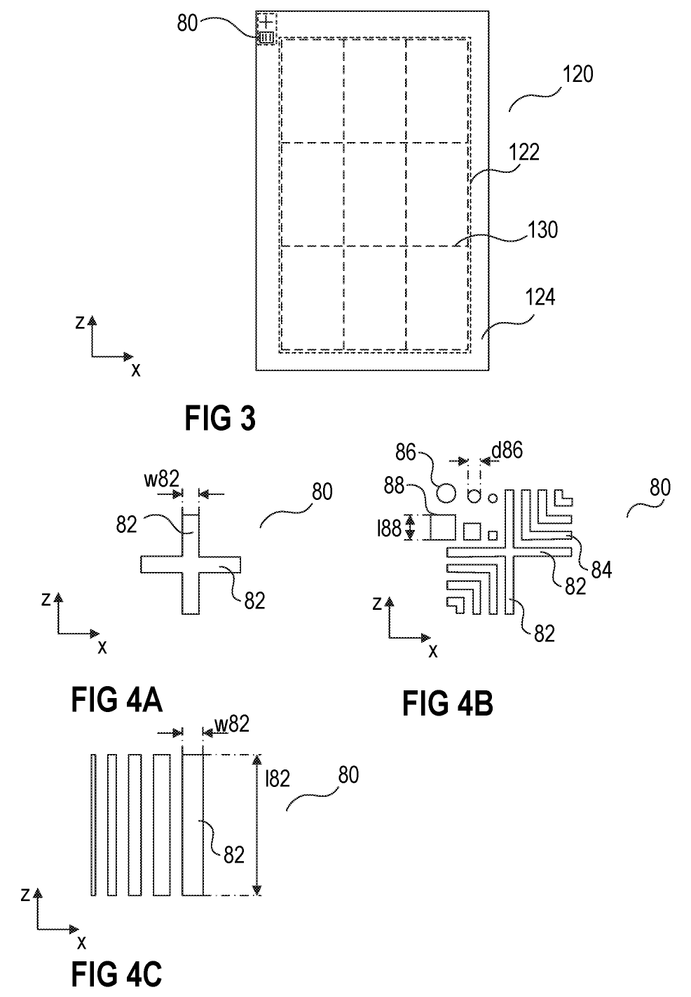

Now referring to FIG. 3, an arrangement according to embodiments of the disclosure is schematically illustrated. The arrangement comprises a dielectric insulation layer 11, and a first metallization layer 111 arranged on a top surface of the dielectric insulation layer 11 (first metallization layer 111 not specifically illustrated in FIG. 3), wherein the first metallization layer 111 is a structured layer that comprises recesses between different sections of the layer 111. The dielectric insulation layer 11 comprises an active region 122, and a passive region 124. While the passive region 124 is shown here to surround the active region 122, it may instead be located adjacent to or even in an area completely surrounded by the active region 122. That is, generally speaking, the dielectric insulation layer 11 comprises an active region 122, and a passive region 124 spaced from the active region 122 in a lateral direction. At least one section of the first metallization layer 111 is arranged in the active region 122. The arrangement further comprises a first test pattern 80 arranged in a top surface of an additional section of the first metallization layer 111 arranged in the passive region 124, and/or in a top surface of a portion of the dielectric insulation layer 11 arranged in the passive region 124 and uncovered by the first metallization layer 111, wherein the first test pattern 80 comprises a plurality of recesses extending from the respective top surface into the additional section of the first metallization layer 111 or into the portion of the dielectric insulation layer 11 in a vertical direction y perpendicular to the top surface, the top surface of the additional section of the first metallization layer 111 being a surface facing away from the substrate 10.

The active region 122 is a region in which current carrying elements are or will be arranged. That is, the active region 122 comprises one or more sections of the first metallization layer 111 that are configured to be coupled to a defined electrical potential during the use of a power semiconductor module arrangement. The one or more semiconductor bodies 20, any terminal elements 4, and electrical connections 3, for example, are generally arranged in the active region 122. The passive region 124 generally does not comprise any current carrying elements. The passive region 124 is generally removed before arranging a substrate 10 in a power semiconductor module arrangement.

The arrangement may be a master card 120 configured to be separated into a plurality of substrates 10 for semiconductor module arrangements. It is, however, also possible that the arrangement comprises only a single substrate 10, the single substrate 10 forming the active region 122 and being surrounded by the passive region 124.

As mentioned above, at least one section of the first metallization layer 111 is arranged in the active region 122. The test pattern 80 may be arranged in or may comprise an additional section of the first metallization layer 111 which, however, does not have any function in a semiconductor module arrangement comprising one or more of the plurality of substrates 10. Defined structures (i.e. recesses) are formed in the additional section of the first metallization layer 111 for evaluation purposes only. That is, different process steps that are required to produce elements and/or structures in the active region 122, are also used to produce the test pattern 80 in the passive region 124. As the test pattern 80 is formed in the edge region 124, it does not require any additional space in the active region 122. As the passive region 124 is generally removed before arranging a substrate 10 of the arrangement in a semiconductor module arrangement, a size of the resulting semiconductor module arrangement does not increase due to the test pattern 80.

The test pattern 80 may also be placed elsewhere on the substrate 10. Instead of using a passive additional section of the metallization layer 111 arranged, e.g., in the passive region 124, the test pattern 80 may be placed directly on a portion of the dielectric insulation layer 11 arranged in the passive region 124 and uncovered by the metallization layer 111. This location could be advantageous where the process to be measured is related to separation of the substrate 10 from a master card 120, for example. The test pattern 80 could also be located on the back side metallization layer 112. Such a location could be advantageous, for example, where front side passive regions 124 are few in number, too small or inconveniently positioned to serve as effective test regions. It is also contemplated that test patterns 80 could be provided in two or more of these different locations.

Now referring to FIGS. 4A, 4B, and 4C, different examples of test patterns 80 are schematically illustrated. The plurality of recesses may comprise at least one of a first elongated trench 82 and a second elongated trench 82, wherein the first elongated trench 82 and the second elongated trench 82 intersect with each other (see, e.g., FIGS. 4A, 4B), one or more elongated trenches 82 not intersecting with any other recesses, each elongated trench 82 having a length l82 in a first horizontal direction that is at least three times a width w82 of the respective elongated trench 82 in a second horizontal direction perpendicular to the first horizontal direction, and perpendicular to the vertical direction y (see, e.g., FIG. 4C), one or more L-shaped trenches 84 (see, e.g., FIG. 4B), one or more circular holes 86 (see, e.g., FIG. 4B), and one or more square shaped holes 88 (see, e.g., FIG. 4B). The specific arrangement of the different recesses in the Figures is merely an example. Recesses of any shapes may generally be suitably combined with each other in order to form the test pattern 80.

According to one embodiment of the disclosure, the plurality of recesses may comprise at least one of a plurality of elongated trenches 82, wherein each elongated trench 82 of the plurality of elongated trenches 82 has a width w82 that differs from the widths w82 of the remaining elongated trenches 82, a plurality of circular holes 86, wherein each circular hole 86 of the plurality of circular holes 86 has a diameter d86 that differs from the diameters d86 of the remaining circular holes 86, and a plurality of square shaped holes 88, wherein each square shaped hole 88 of the plurality of square shaped holes 88 has a lateral length l88 that differs from the lateral lengths l88 of the remaining square shaped holes 88. Of course, any combination of trenches 82, circular holes 86, square-shaped holes 88, and shape of any other kind may be used having various widths and spacings as appropriate, depending on the process to be measured. Moreover, these features could be of a negative character rather than a positive character. For example, material could be removed around a circular region leaving a circular protrusion, rather than a circular hole 86.

For example, each elongated trench 82 in the plurality of elongated trenches 82 may have a width of between 0.2mm and 2mm, each circular hole 86 in the plurality of circular holes 86 may have a diameter d86 of between 0.2mm and 1mm, and/or each square shaped hole 88 in the plurality of square shaped holes 88 may have a lateral length l88 of between 0.05mm and 2mm. A depth of the one or more recesses in the vertical direction y may be between 0.2mm and 0.5mm, for example. According to some examples, each recess of the plurality of recesses may have a depth in the vertical direction y that equals the depth of the remaining recesses of the one or more recesses.

According to some embodiments of the present disclosure, the arrangement may further comprise a second test pattern 80, wherein the first test pattern 80 is arranged in the top surface of an additional section of the first metallization layer 111 arranged in the passive region 124, and the second test pattern 80 is provided in the top surface of a portion of the dielectric insulation layer 11 arranged in the passive region 124 and uncovered by the first metallization layer 111.

One or more recesses in the dielectric insulation layer 11 may be formed by means of laser scribing or laser marking processes, for example, which are also used during production of the arrangement. The additional section of the first metallization layer 111 may be formed in the same way and using the same process steps as all other sections of the first metallization layer 111 on the dielectric insulation layer 11. One or more recesses in the additional section of the first metallization layer 111 may be formed using the same process steps (e.g., etching) as for any other recesses formed in the first metallization layer 111.

By evaluating the test pattern 80, it is therefore possible to determine an accuracy of the process steps, and to further determine a deviation from any desired values (e.g., dimensions, and positions of the sections of the first metallization layer 111 on the dielectric insulation layer 11). A method for determining an accuracy of one or more process steps that are performed during production of the arrangement according to embodiments of the disclosure comprises determining at least one dimension of each recess of the plurality of recesses of the first test pattern 80 of the arrangement, determining a position of the first test pattern 80 with respect to at least one section of the first metallization layer 111 other than the additional section of the first metallization layer 111, and determining a deviation of each of the determined dimensions from a respective target value, and a deviation of the position of the first test pattern 80 from a desired target position.

That is, for example, different dimensions of recesses as illustrated in FIG. 4B may be evaluated. For example, a depth of each of the plurality of recesses in the vertical direction may be determined. Additionally or alternatively, a width and/or length of the L-shaped trenches may be determined. Alternatively or additionally, diameters d86 of circular holes 86 may be determined. Alternatively or additionally, a lateral length l88 of each square shaped hole 88 may be determined. Even further, a position of at least one recess with respect to other structures of the arrangement (e.g., with respect to one or more other sections of the first metallization layer 111, or with respect to a corner of the dielectric insulation layer 11) may be determined. In this way, it is possible to determine a general accuracy of the different process steps that are used to produce the arrangement.

As mentioned before, the process parameters are generally stable during production of a plurality of substrates 10, and a plurality of master cards. That is, the evaluation of the test pattern 80 generally only needs to be performed once. That is, a test pattern 80 on only one arrangement may be sufficient for evaluation. The results of this evaluation are also applicable for any other substrates 10 and master cards produced by means of the same process steps and under the same process conditions. However, it is also contemplated that test patterns from different substrates 10 be compared to one another, to ensure consistency.

Generally, if a deviation of each of the determined dimensions from the respective target value is below a first threshold, and a deviation of the position of the test pattern 80 from a desired target position is below a second threshold, the accuracy of the one or more process steps that are performed during production of the arrangement may be identified as acceptable. This applies for all arrangements (e.g., substrates 10, or master cards) produced under the same process conditions. Any deviations from desired dimensions and/or positions may be taken into account during further assembly of each substrate 10 produced under the same process conditions (e.g., when arranging further components on the substrates 10). This applies for different substrates 10 having the same layout, as well as for substrates 10 having a different layout but produced under the same process conditions at the same supplier. When producing substrates 10 having different layouts, all process parameters may generally remain stable. Merely a different mask may be used (e.g., during an etching process when structuring the first metallization layer 111, or during a deposition process used for forming the first metallization layer 111) for substrates 10 having different layouts. Using a different mask, however, generally does not influence the accuracy of the process steps. Each process step may be evaluated separately, by evaluating the test pattern 80. It is, however, also possible to evaluate each process step with respect to one or more other process steps that are used to produce the arrangement.

The test pattern may be evaluated only once for a plurality of arrangements (e.g., substrates 10 or master cards) produced by means of the same process steps and under the same process conditions. It is, however, also possible that the test pattern 80 on different arrangements is evaluated regularly. It is, however, not necessary that a test pattern 80 on each and every arrangement produced by means of the same process steps and under the same process conditions be evaluated.

By evaluating the test pattern 80 it is, for example, possible to determine the tolerances of an etching process. In order to do so, a deviation of a width of a section of the first metallization layer 111 from a target value and/or a deviation of a width of a trench between two sections of the first metallization layer 111 may be determined by evaluating the test pattern 80. The accuracy of a laser scribing process may be determined by determining a deviation of a width of a recess formed by means of the laser scribing process from a target value. Further, a position of the respective recess with respect to other structures such as, e.g., one or more sections of the first metallization layer 111 may be determined in order to determine an accuracy of the laser scribing process. A quality of a laser marking process may be determined, for example, by determining whether very small recesses may be formed accurately by means of such process, and by further evaluating areas (e.g., distances) between recesses formed by means of the laser marking process.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. An arrangement comprises a dielectric insulation layer, and a first metallization layer arranged on a top surface of the dielectric insulation layer, wherein the first metallization layer is a structured layer that comprises recesses between different sections of the layer, wherein
the dielectric insulation layer comprises an active region, and a passive region spaced from the active region in a lateral direction,
at least one section of the first metallization layer is arranged in the active region,
the arrangement further comprises a first test pattern arranged in a top surface of an additional section of the first metallization layer arranged in the passive region, and/or in a top surface of a portion of the dielectric insulation layer arranged in the passive region and uncovered by the first metallization layer, wherein the first test pattern comprises a plurality of recesses extending from the respective top surface into the additional section of the first metallization layer or into the portion of the dielectric insulation layer in a vertical direction perpendicular to the top surface, the top surface of the additional section of the first metallization layer being a surface facing away from the substrate.

2. The arrangement of claim 1, wherein the active region comprises one or more substrates for semiconductor module arrangements.

3. The arrangement of claim 1, wherein the plurality of recesses comprises:
a first elongated trench and a second elongated trench, wherein the first elongated trench and the second elongated trench intersect with each other.

4. The arrangement of claim 1, wherein the plurality of recesses comprises:
one or more elongated trenches not intersecting with any other recesses, each elongated trench having a length in a first horizontal direction that is at least three times a width of the respective elongated trench in a second horizontal direction perpendicular to the first horizontal direction, and perpendicular to the vertical direction.

5. The arrangement of claim 1, wherein the plurality of recesses comprises at least one of:
one or more L-shaped trenches,
one or more circular holes, and
one or more square shaped holes.

6. The arrangement of claim 1, wherein the plurality of recesses comprises at least one of:
a plurality of elongated trenches, wherein each elongated trench of the plurality of elongated trenches has a width that differs from the widths of the remaining elongated trenches,
a plurality of circular holes, wherein each circular hole of the plurality of circular holes has a diameter that differs from the diameters of the remaining circular holes, and
a plurality of square shaped holes, wherein each square shaped hole of the plurality of square shaped holes has a lateral length that differs from the lateral lengths of the remaining square shaped holes.

74. The arrangement of claim 1, wherein the plurality of recesses comprises at least one of:
a plurality of elongated trenches having a width between 0.2 mm and 2.0 mm, wherein the width of each elongated trench is different from the widths of the remaining elongated trenches,
a plurality of circular holes having a diameter between 0.2 mm and 1.0 mm, wherein the diameter of each circular hole is different from the diameters of the remaining circular holes, and
a plurality of square shaped holes having a lateral length between 0.05 mm and 2.0 mm, wherein the lateral length of each each square shaped hole of the plurality of square shaped holes has a lateral length different from the lateral lengths of the remaining square shaped holes.

8. The arrangement of claim 1, wherein a depth of the one or more recesses in the vertical direction is between 0.2mm and 0.5mm.

9. The arrangement of claim 8, wherein each recess of the plurality of recesses has a depth in the vertical direction that equals the depth of the remaining recesses of the one or more recesses.

10. The arrangement of claim 1, further comprising a second test pattern, wherein the first test pattern is arranged in the top surface of an additional section of the first metallization layer arranged in the passive region, and the second test pattern is provided in the top surface of a portion of the dielectric insulation layer arranged in the passive region and uncovered by the first metallization layer.

11. A method for determining an accuracy of one or more process steps that are performed during production of an arrangement of claim 1, the method comprising:
determining at least one dimension of each recess of the plurality of recesses of the first test pattern of the arrangement,
determining a position of the first test pattern with respect to at least one section of the first metallization layer other than the additional section of the first metallization layer, and
determining a deviation of each of the determined dimensions from a respective target value, and a deviation of the position of the first test pattern from a desired target position.

12. The method of claim 11 further comprising, if a deviation of each of the determined dimensions from the respective target value is below a first threshold, and a deviation of the position of the first test pattern from a desired target position is below a second threshold, identifying the accuracy of the one or more process steps that are performed during production of the arrangement as acceptable.
